(19) United States
(12) Patent Application Publication
(10) Pub. No.: US 2016/0111643 A1
(43) Pub. Date: Apr. 21, 2016

(54) TOPOLOGICAL INSULATOR FORMED NEW SURFACE ELECTRONIC STATE AND THE PREPARATION METHOD THEREOF

(71) Applicants: INSTITUTE FOR BASIC SCIENCE, Daejeon (KR); POSTECH ACADEMY-INDUSTRY FOUNDATION, Pohang-si (KR)

(72) Inventors: Han-Woong YEOM, Pohang-si (KR); Sung-Hwan KIM, Seoul (KR)

(21) Appl. No.: 14/886,736

(22) Filed: Oct. 19, 2015

(30) Foreign Application Priority Data
Oct. 20, 2014 (KR) 10-2014-0141730

(51) Int. Cl. H01L 49/00

(52) U.S. Cl. CPC H01L 49/003

(57) ABSTRACT

The disclosure describes a topological insulator having a new surface electronic state and a preparation method thereof, and more particularly, to a topological insulator having a new surface electronic state, the topological insulator including a unimolecular metal layer formed on a 3D topological insulator, and a method of preparing a topological insulator having a new surface electronic state, the method including: heating and cooling at least one selected from the group consisting of tellurium (Te) and selenium (Se), and bismuth (Bi) to prepare an alloy; and forming a unimolecular metal layer on the alloy.

### BACKGROUND OF THE INVENTION

1. Field of the Invention

The present invention relates to a topological insulator having a new surface electronic state and a preparation method thereof, and more particularly, to a topological insulator in which a surface state of the topological insulator, which is difficult to change, is changed into a new surface electronic state while maintaining a topological characteristic by growing a unimolecular metal layer.

2. Description of the Related Art

Topological insulators (Tis) are new types of insulation materials having a unique surface metal electronic channel. This surface channel has a massless Dirac electron characteristic having a helical spin polarization, and the Dirac electron characteristic is protected by the topological essence of bulk materials. This unique characteristic provides a surface state of a topological insulator, a geometric surface state, an ideal dispersion-free carrier and a fault-tolerant quantum computing.

This material may not be directly used because of material problems such as surface and bulk defects and the surface electronic state characteristics (essentially difficult to manipulate and controlled). Conventionally, the most general method for controlling the topological surface state is doping. In the case of the 3D topological insulator of Bi chalcogenide, which is the most widely researched, nonmagnetic atoms and molecule dopants show the movement of the topological surface state band. In another aspect, magnetic impurity atoms are reported to open a small bandgap at a Dirac point of a topological surface state by breaking a time reversal symmetry. However, the topological characteristic of the material is destroyed, and the magnetic impurity creates undesirable scattering. Recently, a method of altering effective mass of the topological surface state by completing a surface constituted by a different atom with another different atom and a method of altering a vertical position and a Dirac point of a geometric surface state by covering a surface with an ultra-thin layer of an insulator are proposed, however, the topological insulator, in which the topological surface state altered, is practically nonexistent.

As a related art, a doped Bi₂Te₃ thermoelectric material and a method of preparing the same is disclosed in Korean Unexamined Patent Publication No. 10-2012-0050905 (published on May 21, 2012).

### SUMMARY OF THE INVENTION

Therefore, an object of the present invention is to provide a topological insulator having a new surface electronic state while maintaining characteristics of the topological insulator, and a preparation method thereof.

Objects of the present invention may not be limited to the above objects, and other objects will be clearly understandable to those having ordinary skill in the art from the disclosures provided below.

To achieve the object, the present invention provides a topological insulator having a new surface electronic state including a unimolecular metal layer formed on a 3D topological insulator.

The 3D topological insulator may include one selected from the group consisting of Bi₂Te₂Se, Bi₂Se₃ and Bi₂Te₃, and the metal layer may include bismuth (Bi) or antimony (Sb).

In addition, the present invention provides a method of preparing a topological insulator having a new surface electronic state, the method including: heating and cooling a at least one selected from the group consisting of tellurium (Te) and selenium (Se), and bismuth (Bi) to prepare an alloy; and forming a unimolecular metal layer on the alloy.

The heating may be performed at 800° C. to 1100° C.

The cooling may be performed at 550° C. to 650° C.

The metal layer may include bismuth (Bi) or antimony (Sb).

The unimolecular metal layer may be formed by evaporating a metal in an ultrahigh vacuum state.

In addition, the present invention provides a method of preparing a topological insulator having a new surface electronic state, the method including: heating and cooling at least one selected from the group consisting of tellurium (Te) and selenium (Se), and bismuth (Bi) to prepare a single crystal alloy; cleaving a surface of the prepared single crystal alloy in an ultrahigh vacuum state; and forming a unimolecular metal layer on the cleaved surface of the single crystal alloy.

The ultrahigh vacuum state may include 1×10⁻¹¹ to 5×10⁻¹⁰ Torr.

According to the present invention, a unimolecular metal layer is strongly coupled to an upper part of a 3D topological insulator, and specifically, a topological surface state is changed to a new helical spin electronic state while the characteristic of the topological insulator is maintained.

In addition, dispersion and spin direction, which is different from the topological surface state of the 3D topological insulator, are formed on the surface so that the surface state is replaced or converted to a different helical Dirac electronic state while maintaining the characteristic of the topological insulator, thus topologically protected spin and electronic channel are newly formed or adjusted.

### BRIEF DESCRIPTION OF THE DRAWINGS

FIG. 1 is a topological insulator having a unimolecular metal layer in (a), a topological insulator having a unimolecular metal layer on an upper part of the 3D topological insulator in (b), and a scanning tunneling microscope (STM) picture showing a 3D topological insulator in (c).

FIG. 2 shows a calculation result when a coupling distance between Bi₂Te₂Se and Bi is 3 Å in (a), a calculation result when a coupling distance between Bi₂Te₂Se and Bi is 2 Å in (b), a calculation result when a coupling distance between Bi₂Te₂Se and Bi is 1 Å in (c), a calculation result when a coupling distance between Bi₂Te₂Se and Bi is 0.5 Å in (d), a calculation result when a coupling distance between Bi₂Te₂Se and Bi is 0 Å in (e).

FIG. 3 shows an electronic structure which measures a surface state of Bi₂Te₂Se by angle resolved photoemission spectroscopy in (a), and an electronic structure which measures a surface state of Bi grown on Bi₂Te₂Se according to the present invention by angle resolved photoemission spectroscopy in (b).

FIG. 4 shows a theoretical calculation result of BI and B₂ bands with respect to an in-plane of a spin component in (a), a theoretical calculation result of B₁ and B₂ bands with respect to an out-plane of a spin component in (b), a graph showing a spin-polarized photoelectron intensity of BI and B₂ bands with an in-plane direction of a spin component measure by spin and angle resolved photoemission spectroscopy (SARPES) in (c), and a graph showing a spin-polarized photoelectron intensity of BI and B₂ bands with an out-plane direction of a spin component measure by spin and angle resolved photoemission spectroscopy in (d).

FIG. 5 shows a scanning tunneling microscope (STM) picture of the topological insulator according to the present invention in (a), a scanning tunneling spectrum result measured at an edge of a Bi unimolecular layer in (b), a Fourier conversion result of the scanning tunneling spectrum result in (c), a constant-energy contour line and a spin structure calculated at a Fermi level in (d) and a constant-energy contour line and a spin structure calculated at −300 mV.

FIG. 6 shows a calculation result of an electronic structure according to the 3D topological insulator in the topological insulator according to the present invention. Specifically, FIG. 6 shows a calculation result of an electronic structure between Bi₂Se₃ and Bi metal structures in (a), a calculation result of an electronic structure between Bi₂Te₂ and Bi metal structures in (b), a calculation result of an electronic structure between Bi₂Te₂Se and Bi metal structures in (c) and a calculation result of an electronic structure between Sb₂Te₃ and Bi metal structures in (d).

FIG. 7 shows a calculation result of an electronic structure between In₂Se₃ and Bi metal structures in (a), a calculation result of an electronic structure between Bi₂Te₂Se and Sb metal structures in (b), and a calculation result of an electronic structure between Bi₂Te₂Se and Ge metal structures in (c).

### DETAILED DESCRIPTION OF THE INVENTION

Hereinafter, exemplary embodiment according to the present invention is described in detail with reference to the accompanying drawings.

Advantages and features of the present invention, and method for achieving thereof will be apparent with reference to the examples that follow.

But, it should be understood that the present invention is not limited to the following embodiments and may be embodied in different ways, and that the embodiments are given to provide complete disclosure of the invention and to provide thorough understanding of the invention to those skilled in the art, and the scope of the invention is limited only by the accompanying claims and equivalents thereof.

In addition, when describing embodiments of the present invention, detailed descriptions of well-known functions and structures incorporated herein may be omitted when they make the subject matter of the present invention unclear.

The present invention provides a topological insulator having a new surface electronic state, the topological insulation including a unimolecular metal layer formed on a 3D topological insulator.

The topological insulator according to the present invention includes the unimolecular metal layer strongly coupled to an upper part of the 3D topological insulator, and specifically, changes the original topological surface state to a new helical spin electronic state while maintaining the characteristic of the topological insulator. In addition, dispersion and spin direction, which is different from the topological surface state of the 3D topological insulator, are formed on the surface so that the surface state is replaced or converted to a different helical Dirac electronic state while maintaining the characteristic of the topological insulator, thus topologically protected spin and electronic channel are newly formed or adjusted.

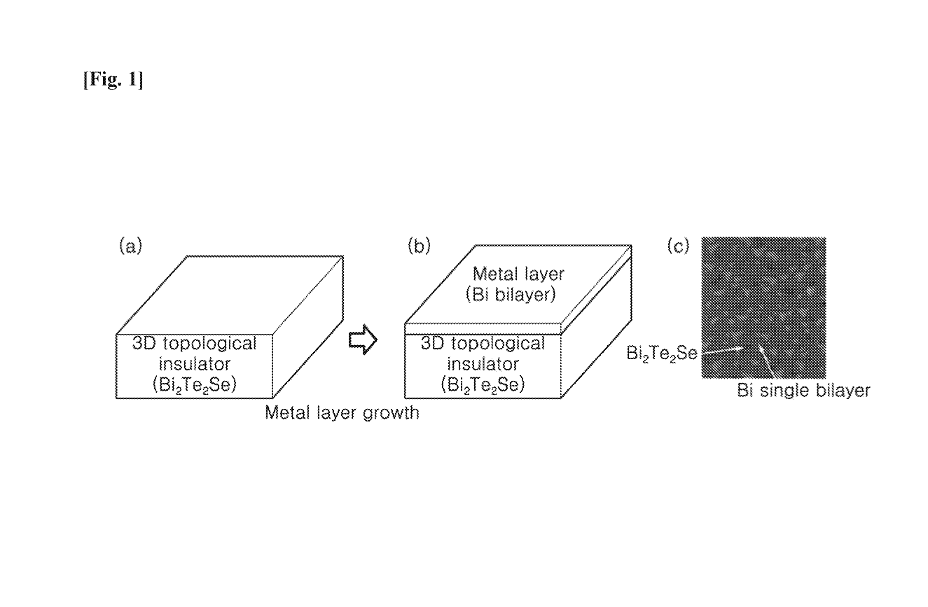

FIG. 1 is a schematic view showing a shape of the topological insulator according to the present invention. As shown in FIG. 1, the metal layer is grown (refer to (b) of FIG. 1) on the 3D topological insulator (refer to (a) of FIG. 1) to prepare a new surface state, and as shown in (c) of FIG. 1, when observed by a scanning tunneling microscope (STM), a Bi unimolecular metal layer is properly grown.

In the topological insulator having the new surface electronic state according to the present invention, the 3D topological insulator may include one selected from the group consisting of Bi₂Te₂Se, Bi₂Se₃ and Bi₂Te₃, the metal layer may include bismuth (Bi) or antimony (Sb), and a unimolecular metal layer, in which two uniatomic layers of Bi or Si are coupled, is formed so that a new surface electronic state may be formed on the upper part of the 3D topological insulator.

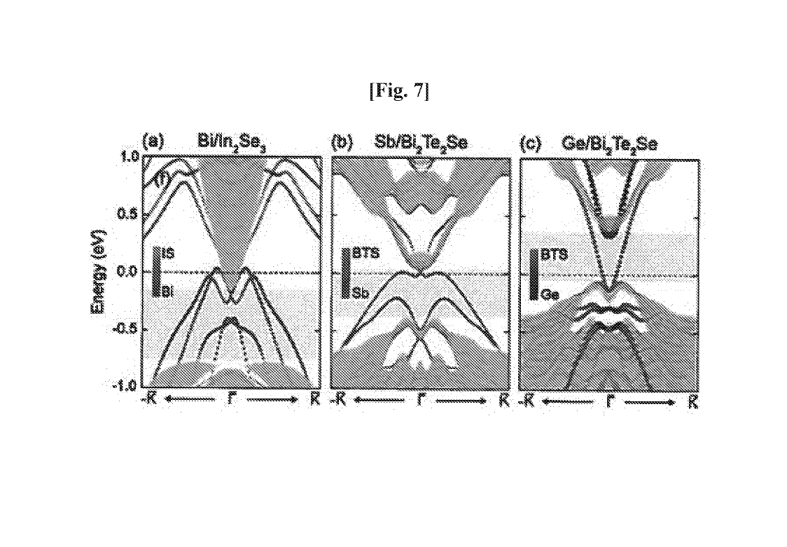

In addition, in the topological insulator according to the present invention, as shown in FIG. 7, when a Bi metal layer is formed on an upper part of In₂Se₃, which is a normal insulator, the surface state of the topological insulator is not formed, and when a Ge layer is formed, the surface state of the topological insulator is not formed.

In addition, the present invention provides a method of preparing a topological insulator having a new surface electronic state, the method including: heating and cooling at least one selected from the group consisting of tellurium (Te) and selenium (Se), and bismuth (Bi) to prepare an alloy; and forming a unimolecular metal layer on the alloy.

The method of preparing a topological insulator having a new surface electronic state according to the present invention includes heating and cooling one selected from the group of tellurium (Te) and selenium (Se), and bismuth (Bi) to prepare an alloy.

In this case, the heating is preferably performed at 800 to 1100° C. When the heating is performed at lower than 800° C., metals in liquid states do not properly mix, and when exceeding 1100° C., the quartz tube having the specimen become melted.

In addition, the cooling is preferably performed at 550 to 650° C. When the cooling is performed at lower than 550° C., the size of the single crystal becomes small, and when exceeding 650° C., the crystallization is very slowly progressed, so the process time becomes longer.

In addition, the cooling is preferably slowly performed for one week. When the cooling is performed less than one week, the size of the single crystal may be small, and when exceeding one week, the size of the single crystal does not become larger.

Next, the method of preparing a topological insulator having a new surface electronic state according to the present invention includes forming a unimolecular metal layer on the alloy.

The metal layer may include bismuth (Bi) or antimony (Sb), and the unimolecular metal layer formed by molecular beam epitaxy through evaporating the metal in an ultrahigh vacuum state.

In addition, the present invention provides the method of preparing a topological insulator having a new surface electronic state, the method including: heating and cooling one selected from the group consisting of tellurium (Te) and selenium (Se), and bismuth (Bi) to prepare a single crystal alloy; cleaving a surface of the prepared single crystal alloy in an ultrahigh vacuum state; and forming a unimolecular metal layer on the cleaved surface of the single crystal alloy.

The method of preparing a topological insulator having a new surface electronic state according to the present invention includes a process for forming a cleavage on the surface of the prepared single crystal alloy in the ultrahigh vacuum state so that the surface of the 3D topological insulator may be used. The ultrahigh vacuum state is preferably 1×10⁻¹¹ to 5×10⁻¹⁰ Torr. Although a more uncontaminated surface of the 3D topological insulator may be obtained when the ultrahigh vacuum state is lower, the ultrahigh vacuum state less than 1×10⁻¹¹ Torr is difficult to implement, and when exceeding 5×10⁻¹⁰ Torr, the surface of the 3D topological insulator becomes contaminated.

### Embodiment 1

### Preparing the Topological Insulator Having the Bi or Sb Unimolecular Metal Layer on Bi₂Te₂Se

The 3D topological insulator was prepared by a self-flux method after mixing Bi, Te and Se powders. The Bi, Te and Se powders are inserted into a quartz tube and maintained at 850° C. for 2 days and slowly cooled to 600° C. for one week. The prepared single crystal 3D topological insulator was cleaved in ultrahigh vacuum for an uncontaminated surface. Then, the topological insulator was prepared by growing a single layer by using a Bi or Sb deposition device.

### Embodiment 2

### Preparing the Topological Insulator Having Bi or Sb Unimolecular Metal Layer on Bi₂Se₂

Except for preparing the 3D topological insulator by mixing Bi and Se powders, the topological insulator was prepared by the same method as Embodiment 1.

### Embodiment 3

### Preparing the Topological Insulator Having Bi or Sb Unimolecular Metal Layer on Bi₂Te₃

Except for preparing the 3D topological insulator by mixing Bi and Te powders, the topological insulator was prepared by the same method as Embodiment 1.

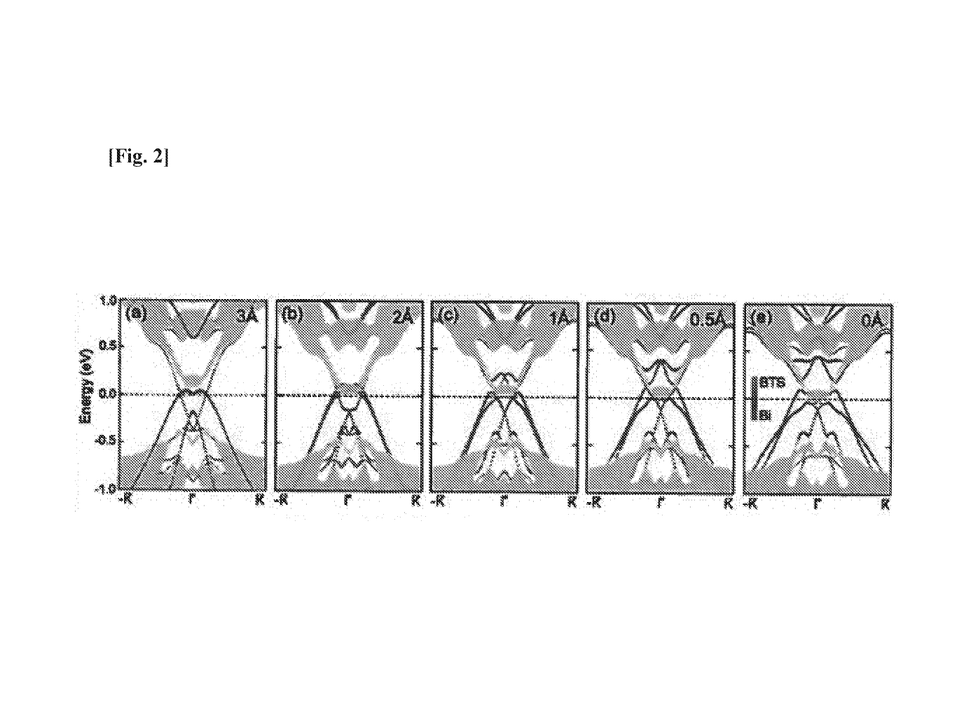

FIG. 2 shows a calculation result of an electronic structure according to the coupling distance between Bi₂Te₂Se and Bi in the topological insulator according to the present invention. Specifically, FIG. 2 shows a calculation result when a coupling distance between Bi₂Te₂Se and Bi is 3 Å in (a), a calculation result when a coupling distance between Bi₂Te₂Se and Bi is 2 Å in (b), a calculation result when a coupling distance between Bi₂Te₂Se and Bi is 1 Å in (c), a calculation result when a coupling distance between Bi₂Te₂Se and Bi is 0.5 Å in (d), a calculation result when a coupling distance between Bi₂Te₂Se and Bi is 0 Å in (e).

In FIG. 2, the part in purple is the electronic structure resulting from Bi₂Te₂Se, and the part in blue is the electronic structure resulting from Bi. When the coupling distance between the Bi₂Te₂Se and Bi metal layers was 3 Å, the electronic structure were not influenced by each other ((a) of FIG. 2), and the most stable state was when the coupling distance between the Bi₂Te₂Se and Bi metal layers was 0 Å ((e) of FIG. 2). In other words, when the Bi₂Te₂Se and Bi metal layers did not interact with each other, the surface state of Bi₂Te₂Se still exists, but a new surface resulting from the Bi metal layer is created as the coupling distance becomes shorter.

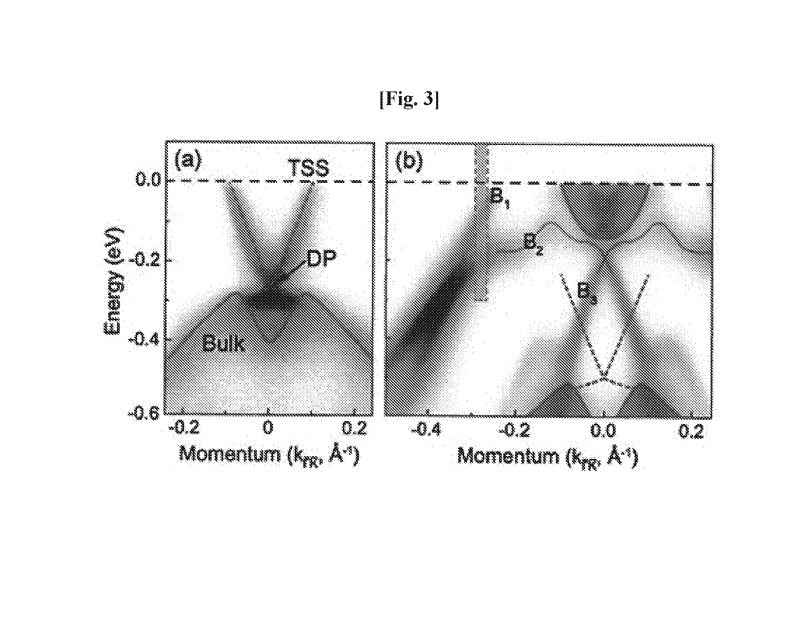

FIG. 3 shows the electronic structure measured by an angle resolved photoemission spectroscopy. FIG. 3 shows an electronic structure, in which the surface state of Bi₂Te₂Se is measured by the angle resolved photoemission spectroscopy in (a), and the electronic structure, in which the surface state of Bi grown on Bi₂Te₂Se according to the present invention measured by the angle resolved photoemission spectroscopy in (b). In FIG. 3, the green dotted line shows the electronic structure of the surface state of Bi₂Te₂Se, and the solid line shows the electronic structure of Bi₂Te₂Se bulk.

As shown in FIG. 3, when the Bi metal layer is formed, the original surface state of the 3D topological insulator disappears and the new surface state resulting from the electronic structure of Bi is created. One of the characteristics of the surface state of the topological insulator is that bands are crossed odd number of times between TRIM (tim-reversal invariant momenta) in the band gap. In other words, as shown in (a) of FIG. 3, bands are crossed odd number of times between Γ and K, which is the TRIM point. In addition, as shown in (b) of FIG. 3, the electronic band dispersion of Bi₂Te₂Se (according to Γ-K direction) gradually changes after the Bi unimolecular layer is formed. The Bi₂Te₂Se bulk band is shifted to 0.2 eV from the Bi unimolecular layer because of charge transfer. This enables the conduction band of the bulk surface to appear equal to or less than the Fermi energy near the Γ point. The topological surface state of Bi₂Te₂Se completely disappears, ̂ shaped band is created near the Γ point. In addition, two strong dispersion states appear apart from the Γ. In other words, B₁ crosses the Fermi level, and B₂ forms a new band crossing (blue dotted line in FIG. 3) and is connected to the ̂ shaped band B₃ in Γ. The new surface state of B₁, B₂ and B₃ is created from the Bi unimolecular layer.

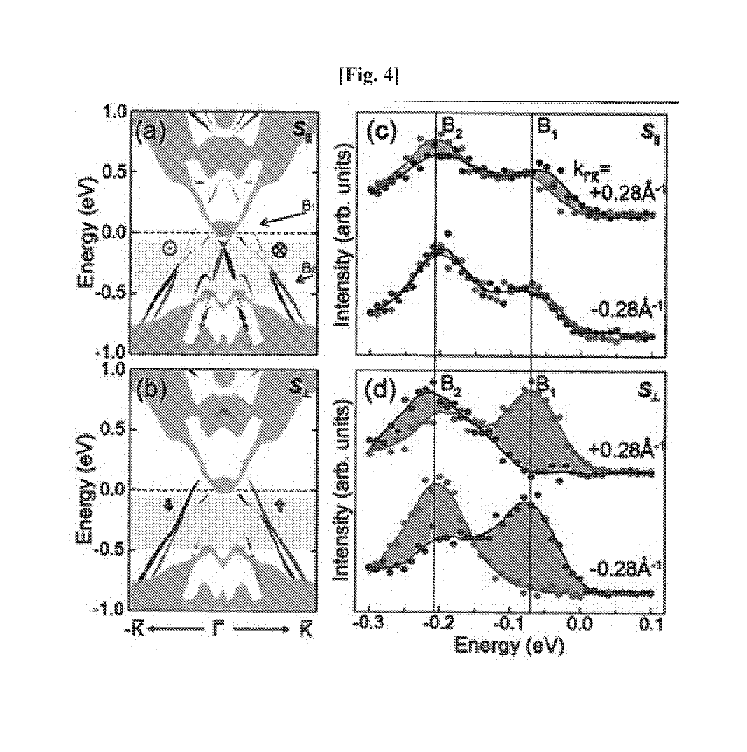

FIG. 4 shows a theoretical calculation result and an analysis result and spin and angle resolved photoemission spectroscopy (SARPES) of a spin structure in the topological insulator according to the present invention. Specifically, FIG. 4 shows a theoretical calculation result of B₁ and B₂ bands with respect to an in-plane of a spin component in (a) and a theoretical calculation result of B₁ and B₂ bands with respect to an out-plane of a spin component in (b). In (a) and (b) of FIG. 4, the gray part shows the Bi₂Te₂Se bulk band, and the band from Bi is shown in blue. In addition, FIG. 4 shows a graph showing a spin-polarized photoelectron intensity of B₁ and B₂ bands with an in-plane direction of a spin component measure by spin and angle resolved photoemission spectroscopy (SARPES) in (c), and a graph showing a spin-polarized photoelectron intensity of B₁ and B₂ bands with an out-plane direction of a spin component measure by spin and angle resolved photoemission spectroscopy in (d).

As shown in FIG. 4, when the experiment results measured by the theoretical calculations and angle resolved photoemission spectroscopy is examined, the spin electronic structure of B₁ and B₂ is marginal in the parallel direction and strong in the vertical direction. This shows that the electronic spin shape of the surface state is fixed in a helical shape.

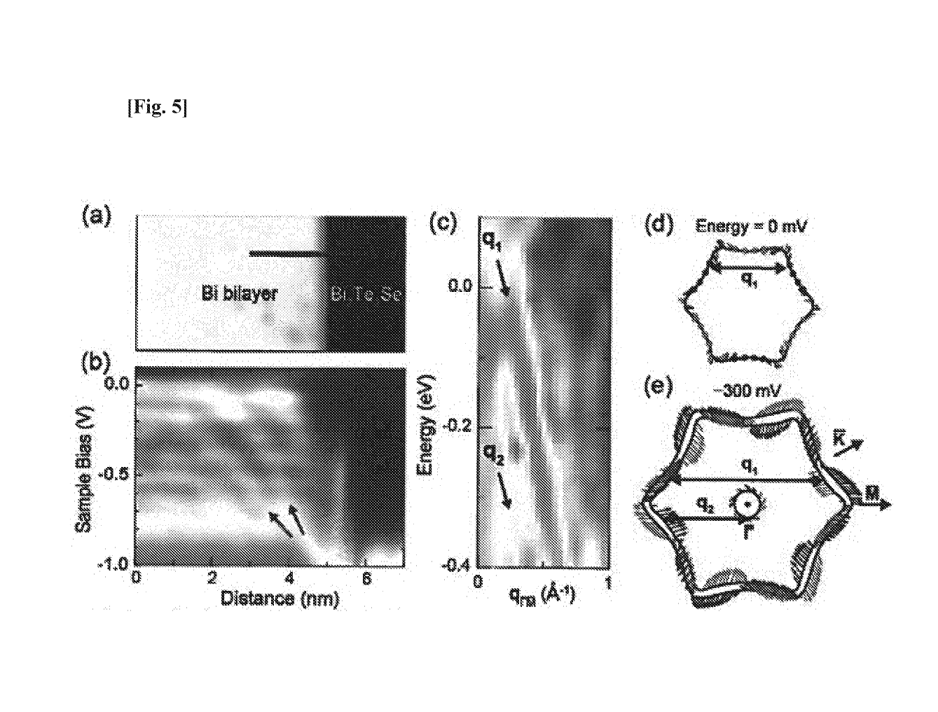

FIG. 5 shows the measurement result of a local electronic density at a edge of the Bi metal layer of the topological insulator according to the present invention. Specifically, FIG. 5 shows a scanning tunneling microscope (STM) picture of the topological insulator according to the present invention in (a), a scanning tunneling spectrum result measured at an edge of a Bi unimolecular layer in (b), a Fourier conversion result of the scanning tunneling spectrum result in (c), a constant-energy contour line and a spin structure calculated at a Fermi level in (d) and a constant-energy contour line and a spin structure calculated at −300 mV in (e). The electronic density was measured in the direction of the blue arrow of (a) of FIG. 5, and as shown in FIG. 5, the new surface state was also identified in the experiment using the scanning tunneling microscope, and by measuring the local density of states (LDOS) based on the above, the interference phenomenon of electrons scattering at an edge of the Bi metal layer may be observed. This is the result which may be observed only when the spin state is the same in the same energy. When the wave number at a specific energy is measured through the interference phenomenon of the scattered electrons and Fourier transformed, a linear structure, which was observed in the angle resolved photoemission spectroscopy and the first principle calculation, is observed. Be identifying the characteristics of the topological insulator, the newly formed surface state is the topologically protected edge state, the electronic density measured at the Bi edge has a specific patter according to the energy, and the scattered electrons created linear shaped q₁ and q₂.

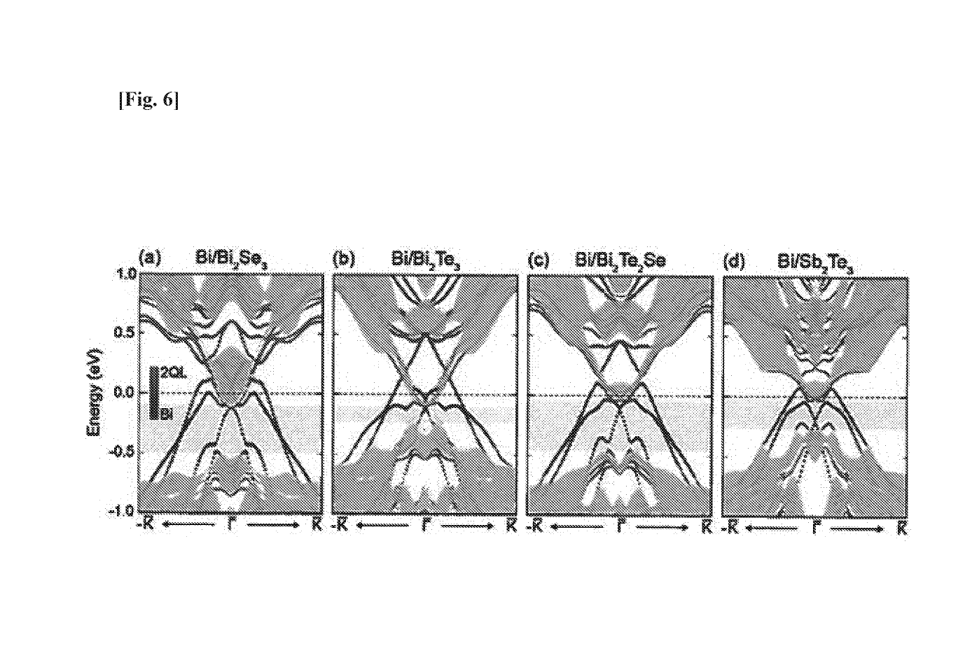

FIG. 6 shows a calculation result of an electronic structure according to the 3D topological insulator in the topological insulator according to the present invention. Specifically, FIG. 6 shows a calculation result of an electronic structure between Bi₂Se₃ and Bi metal structures in (a), a calculation result of an electronic structure between Bi₂Te₂ and Bi metal structures in (b), a calculation result of an electronic structure between Bi₂Te₂Se and Bi metal structures in (c) and a calculation result of an electronic structure between Sb₂Te₃ and Bi metal structures in (d).

As shown in FIG. 6, the surface state of the 3D topological insulator disappears and the electronic structure resulting from Bi creates the new surface state.

FIG. 7 shows a calculation result of an electronic structure according to the 3D topological insulator and the type of the unimolecular metal layer in the topological insulator according to the present invention. Specifically, FIG. 7 shows a calculation result of an electronic structure between In₂Se₃ and Bi metal structures in (a), a calculation result of an electronic structure between Bi₂Te₂Se and Sb metal structures in (b), and a calculation result of an electronic structure between Bi₂Te₂Se and Ge metal structures in (c).

As shown in FIG. 7, in the case of the normal insulator (In₂Se₃), the new surface state resulting from Bi is created, however, the electronic structure corresponding to the Rashba electronic structure appeared, and crossed even number of times between Γ and K in the bandgap (refer to (a) of FIG. 7). In other words, this is not the surface state of the topological insulator. In addition, when Sb is grown rather than Bi on Bi₂Te₂Se, the surface state resulting from the Sb metal layer has the characteristics of the topological insulator (refer to (b) of FIG. 7). Otherwise, when Ge was grown, the surface state of Bi₂Te₂Se does not disappear and the surface state created from Ge did not form.

Therefore, the Bi or Sb unimolecular metal layer is required to be formed to largely change the surface state of the 3D topological insulator, and due to the strong interaction between the grown metal layer and the 3D topological insulator, the surface state of the 3D topological insulator is removed and the new surface state resulting from the Bi or Sb metal layer is created.

What is claimed is:

1. A topological insulator having a new surface electronic state, the topological insulator comprising a unimolecular metal layer formed on a 3D topological insulator.

2. The topological insulator of claim 1, wherein the 3D topological insulator includes one selected from the group consisting of Bi₂Te₂Se, Bi₂Se₃ and Bi₂Te₃.

3. The topological insulator of claim 1, wherein the metal layer includes bismuth (Bi) or antimony (Sb).

4. A method of preparing a topological insulator having a new surface electronic state, the method comprising:
heating and cooling at least one selected from the group consisting of tellurium (Te) and selenium (Se), and bismuth (Bi) to prepare an alloy; and
forming a unimolecular metal layer on the alloy.

5. The method of claim 4, wherein the heating is performed at 800° C. to 1100° C.

6. The method of claim 4, wherein the cooling is performed at 550° C. to 650° C.

7. The method of claim 4, wherein the metal layer includes bismuth (Bi) or antimony (Sb).

8. The method of claim 4, wherein the unimolecular metal layer is formed by evaporating a metal in an ultrahigh vacuum state.

9. A method of preparing a topological insulator having a new surface electronic state, the method comprising:
heating and cooling at least one selected from the group consisting of tellurium (Te) and selenium (Se), and bismuth (Bi) to prepare a single crystal alloy;
cleaving a surface of the prepared single crystal alloy in an ultrahigh vacuum state; and
forming a unimolecular metal layer on the cleaved surface of the single crystal alloy.

10. The method of claim 9, wherein the ultrahigh vacuum state includes 1×10⁻¹¹ Torr to 5×10⁻¹⁰ Torr.
